(19) United States
(12) Patent Application Publication
(10) Pub. No.: US 2025/0203950 A1
(43) Pub. Date: Jun. 19, 2025

(54) METHOD FOR MANUFACTURING SEMICONDUCTOR DEVICE

(71) Applicant: SK hynix Inc., Gyeonggi-do (KR)

(72) Inventor: Young Gwang YOON, Gyeonggi-do (KR)

(21) Appl. No.: 18/779,086

(22) Filed: Jul. 22, 2024

(30) Foreign Application Priority Data
Dec. 15, 2023 (KR) 10-2023-0183538

(51) Int. Cl. H01L 29/792; H01L 21/762; H10B 12/00

(52) U.S. Cl. CPC H10D 30/69; H01L 21/76224; H10B 12/01

(57) ABSTRACT

A method for manufacturing a semiconductor device includes forming a first insulation layer over a second region of a semiconductor substrate including first and second regions, forming a capping layer to cover the first insulation layer located over the second region, forming a charge transfer layer over the first region, and forming a second insulation layer over the charge transfer layer located over the first region.

### CROSS-REFERENCE TO RELATED APPLICATION

This patent application claims priority to and benefits of Korean patent application No. 10-2023-0183538, filed on Dec. 15, 2023, which is incorporated herein by reference in its entirety.

### TECHNICAL FIELD

Embodiments of the present disclosure generally relate to a method for manufacturing a semiconductor device, and more particularly to a method for manufacturing a semiconductor device including a charge transfer layer.

### BACKGROUND

As the degree of integration of semiconductor devices increases, the area of a gate of a transistor decreases. Due to a decrease in the area of the gate of the transistor, capacitance of a gate insulation layer of the transistor decreases, and if a thickness of the gate insulation layer is reduced to avoid the decrease in capacitance, leakage current may occur, resulting in deterioration in performance (e.g., reliability) of the transistor. Research and development have been conducted on semiconductor devices and methods for manufacturing the same to prevent deterioration in transistor performance caused by a higher degree of integration of semiconductor devices.

### SUMMARY

In accordance with an embodiment of the present disclosure, a method for manufacturing a semiconductor device may include forming a first insulation layer over a second region of a semiconductor substrate including first and second regions; forming a capping layer to cover the first insulation layer located over the second region; forming a charge transfer layer over the first region; and forming a second insulation layer over the charge transfer layer located over the first region.

In an embodiment, the method may further include forming a device isolation structure to isolate the first region and the second region from each other.

In an embodiment, the method may further include removing the capping layer before the charge transfer and the second insulation layer are formed.

In an embodiment, the first region may include impurities having a first conductivity type, and the second region may include impurities having a second conductivity type.

In an embodiment, the first insulation layer may be formed using at least one of a radical oxidation process, atomic layer deposition (ALD), chemical vapor deposition (CVD), or a wet chemical process.

In an embodiment, the semiconductor substrate may include crystalline silicon.

In an embodiment, the charge transfer layer may include a crystal structure having a lattice constant greater than a lattice constant of the crystalline silicon.

In an embodiment, the charge transfer layer may include silicon germanium (SiGe).

In an embodiment, carriers moving inside the charge transfer layer may be holes.

In an embodiment, the capping layer may include silicon nitride-based components.

In an embodiment, the first insulation layer may be thicker than the second insulation layer.

In accordance with an embodiment of the present disclosure, a method for manufacturing an image sensing device may include forming a first insulation layer over one surface of each of second and fourth regions from among first to fourth regions included in a semiconductor substrate; forming a capping layer to cover the first insulation layer located over each of the second and fourth regions; forming a charge transfer layer over one surface of the first region; removing the capping layer after the charge transfer layer is formed; and forming a second insulation layer over each of the charge transfer layers located over the first region, the first insulation layer formed over the second and fourth regions, and one surface of the third region. Each of the first and second regions may include impurities having a first conductivity type, and each of the third and fourth regions may include impurities having a second conductivity type.

In an embodiment, the method may further include forming device isolation structures by which the first to fourth regions are isolated from each other.

In an embodiment, the first insulation layer may be formed using a radical oxidation process, atomic layer deposition (ALD), chemical vapor deposition (CVD), or wet chemical process.

In an embodiment, the semiconductor substrate may include crystalline silicon.

In an embodiment, the charge transfer layer may include a crystal structure having a lattice constant greater than a lattice constant of the crystalline silicon.

In an embodiment, the charge transfer layer may include silicon germanium (SiGe).

In an embodiment, carriers moving inside the charge transfer layer may be holes.

In an embodiment, the first insulation layer may be thicker than the second insulation layer.

In an embodiment, the capping layer may include silicon nitride-based components.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating a semiconductor device according to an embodiment of the present disclosure.

FIGS. 2 to 11 are cross-sectional views illustrating processes of a method for manufacturing the semiconductor device shown in FIG. 1 according to an embodiment of the present disclosure.

### DETAILED DESCRIPTION

The present disclosure provides embodiments and examples of a method for manufacturing a semiconductor device including a charge transfer layer, that may be used in configurations to substantially address one or more technical or engineering issues and to mitigate limitations or disadvantages encountered in some other semiconductor devices. Some embodiments of the present disclosure relate to a semiconductor device that can be manufactured by a simple fabrication process while securing the reliability thereof, and a method for manufacturing the same. In recognition of the issues above, the embodiments of the present disclosure can provide a method for manufacturing a highly reliable semiconductor device by increasing the reliability of a gate insulation layer.

Reference will now be made in detail to the embodiments of the present disclosure, examples of which are illustrated in the accompanying drawings. Wherever possible, the same reference numbers will be used throughout the drawings to refer to the same or like parts. While this disclosure is susceptible to various modifications and alternative forms, specific embodiments thereof are shown by way of example in the drawings. However, this disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized.

In describing the components of the embodiments of the present disclosure, various terms such as first, second, etc., may be used solely for the purpose of differentiating one component from another, but the essence, order and sequence of the components are not limited to these terms. Unless defined otherwise, all terms, including technical and scientific terms, used in the present disclosure may have the same meaning as commonly understood by a person having ordinary skill in the art to which the present disclosure pertains. It will be further understood that terms, such as those defined in commonly used dictionaries, may be interpreted as having a meaning that is consistent with their meaning in the context of the related art and the present disclosure, and should not be interpreted in an idealized or overly formal sense unless expressly so defined herein.

Various embodiments of the present disclosure relate to a semiconductor device that can be manufactured by a simple fabrication process while securing the reliability thereof, and a method for manufacturing the same.

It is to be understood that both the foregoing general description and the following detailed description of the present disclosure are illustrative and descriptive and are intended to provide further description of the embodiments of the present disclosure as claimed.

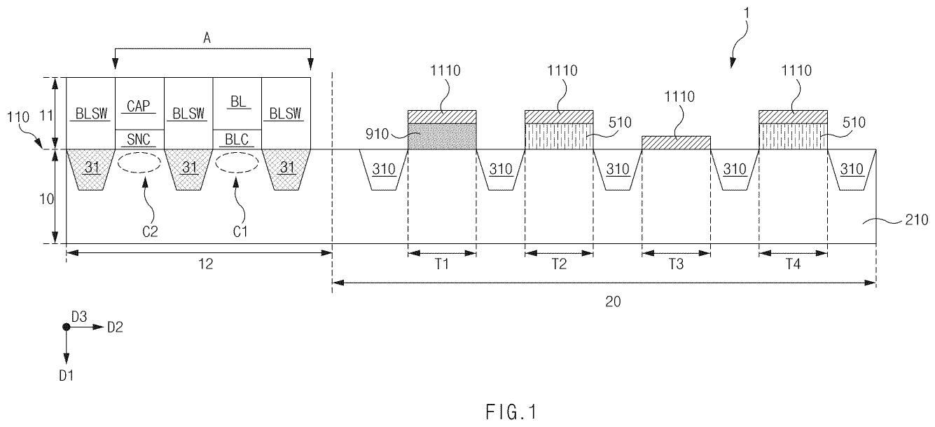

FIG. 1 is a block diagram illustrating a semiconductor device 1 based on an embodiment of the present disclosure.

Referring to FIG. 1, the semiconductor device 1 may be a memory device (e.g., a dynamic random access memory (DRAM)) included in an electronic device (e.g., computer, smartphone, etc.). For example, the semiconductor device 1 of FIG. 1 may illustrate the structure of a DRAM.

The semiconductor device 1 may include a cell region 12 and a peripheral region 20. The cell region 12 may be a region where a cell array is located within the core region of the DRAM, and the peripheral region 20 may be a region where a control circuit within the core region of the DRAM is located.

The cell region 12 may be a region where data can be stored. Data storage may be performed by storing charge in a capacitor (CAP). If charge is stored in the capacitor (CAP) when reading data from the cell region 12, a voltage of a bit line (BL) may slightly increase, and if charge is not stored in the capacitor (CAP) when reading data from the cell region 12, a voltage of the bit line (BL) may slightly decrease. An operation of reading data from the cell region 12 may be performed based on the increased or decreased voltage. When reading data, the peripheral region 20 may perform an operation of amplifying a difference between the increased or decreased voltages using a plurality of transistors. When the difference between voltages is amplified, the peripheral region 20 may more clearly detect whether charge has been stored in the capacitor (CAP), so that the peripheral region 20 can accurately read data. The amplifying operation may be performed, for example, by a bit line sense amplifier.

The cell region 12 may include a portion of a semiconductor substrate 10 and an interconnect region 11. The pattern of section ‘A’ of the cell region 12 may be repeatedly arranged within the cell region 12. In FIG. 1, repeated illustration is omitted for convenience of description.

The semiconductor substrate 10 of the cell region 12 may include an epitaxial region (also called “epitaxial region”) 210, a cell insulation structure 31, a first channel C1, and a second channel C2 included in the cell region 12.

The epitaxial region 210 of the cell region 12 may be the remaining region of the semiconductor substrate 10 other than a cell insulation structure 31. The epitaxial region 210 of the cell region 12 may include a silicon material.

The cell insulation structure 31 may be recessed in a first direction D1 from one surface 110 of the semiconductor substrate 10 in the cell region 12. When charges move to the first channel C1 that can be formed on the epitaxial region 210 of the cell region 12 by a voltage applied to the cell region 12, the cell insulation structure 31 may prevent such charges from moving to the second channel C2.

The first channel C1 may be a path through which charges move in an upper portion of the epitaxial region 210 of the cell region 12 when a voltage is applied to the bit line BL. The second channel C2 may be a path through which charges move in the upper portion of the epitaxial region 210 of the cell region 12 when a voltage is applied from the capacitor CAP to the bit line that can be located in a third direction D3. The charges having moved to the second channel C2 may move to the capacitor (CAP) through a storage node contact (SNC).

The interconnect region 11 may include a bit line (BL), a bit line spacer (BLSW), a bit line contact (BLC), a capacitor (CAP), and a storage node contact (SNC).

The bit line contact (BLC) may contact one surface 110 of the semiconductor substrate 10 and may be disposed at a position where the cell insulation structure 31 is not disposed. The bit line contact (BLC) may provide electrical connection between the bit line (BL) and the epitaxial region 210 that contact the bit line contact (BLC) when a voltage is applied to the bit line (BL).

The bit line (BL) may be disposed over the bit line contact (BLC). The bit line (BL) may include metal and may extend in the third direction D3. Although only one bit line (BL) is shown in FIG. 1, the pattern of section ‘A’ of the cell region 12 may be repeatedly arranged, and a plurality of bit lines (BL) may also be arranged.

The bit line spacer (BLSW) may be disposed on both sides of the bit line (BL) to contact the bit line (BL) in the second direction D2. The bit line spacer (BLSW) may be disposed on one surface 110 of the semiconductor substrate 10 in the cell region 12. The bit line spacer (BLSW) may prevent electrical interaction between the plurality of bit lines (BL).

The storage node contact (SNC) may be disposed spaced apart from the bit line contact (BLC), and may be disposed over one surface 110 of the semiconductor substrate 10 in the cell region 12 where the cell insulation structure 31 is not disposed. The storage node contact (SNC) may provide electrical connection between the capacitor (CAP) and the second channel C2 when the second channel C2 is formed.

When the second channel C2 is formed, the capacitor (CAP) may store the charges having moved from the second channel C2 to the storage node contact (SNC).

The peripheral region 20 may include a semiconductor substrate 10, a first insulation layer 510, a charge transfer layer 910, and a second insulation layer 1110.

The semiconductor substrate 10 in the peripheral region 20 may include an epitaxial region 210 and a device isolation structure 310.

The epitaxial region 210 of the peripheral region 20 may refer to a region of the semiconductor substrate 10 of the peripheral region 20 excluding the region where the device isolation structure 310 is disposed. The epitaxial region 210 of the peripheral region 20 may include a silicon material. A portion of the epitaxial region 210 of the peripheral region 20 may be a region doped with impurities of the first conductivity type (e.g., N-type), and the other portion may be a region doped with impurities of the second conductivity type (e.g., P-type).

The epitaxial region 210 of the peripheral region 20 may include first to fourth transistor regions (T1˜T4). The height of the first to fourth transistor regions (T1˜T4) 4 may be the same as the height of the semiconductor substrate 10 in the first direction D1.

One surface of the first to fourth transistor regions (T1˜T4) may be a portion of one surface 110 of the semiconductor substrate 10 in the peripheral region 20, and the expression “one surface 110 of first to fourth transistor regions (T1˜T4)” may be understood as “portion of one surface 110 of the semiconductor substrate 10 where the first to fourth transistor regions (T1˜T4) are located.”

A charge transfer layer 910 may be disposed over one surface 110 of the first transistor region T1. A second insulation layer 1110 may be disposed over the charge transfer layer 910. The second insulation layer 1110 may be included in the gate insulation layer of the first transistor. The charge transfer layer 910 may improve the mobility of holes in a channel that can be formed under the gate insulation layer of the first transistor. The first transistor may be a P-type metal-oxide-semiconductor field-effect transistor (PMOSFET) that uses holes as carriers, and the first transistor region T1 may include an N-type doped region. Due to the charge transfer layer 910, the first transistor may provide a PMOSFET with a faster operating speed than the second transistor, which will be described later.

A first insulation layer 510 may be disposed over one surface 110 of the second transistor region T2. The second insulation layer 1110 may be disposed over the first insulation layer 510. The first insulation layer 510 and the second insulation layer 1110 may be included in the gate insulation layer of the second transistor. The gate insulation layer of the second transistor may be thicker than the gate insulation layer of the first transistor. The second transistor may be a PMOSFET that uses holes as carriers, and the second transistor region T2 may include an N-type doped region. As the gate insulation layer becomes thicker, the possibility of occurrence of leakage current decreases, and the second transistor may provide a PMOSFET with higher reliability than the first transistor.

The second insulation layer 1110 may be disposed over one surface 110 of the third transistor region T3. The second insulation layer 1110 may be included in the gate insulation layer of the third transistor. The gate insulation layer of the third transistor may be thinner than the gate insulation layer of the fourth transistor, which will be described later. The third transistor may be an N-type metal-oxide-semiconductor field-effect-transistor (NMOSFET) that uses electrons as a carrier, and the third transistor region T3 may include a P-type doped region. As the gate insulation layer becomes thinner, capacitance of the gate insulation layer increases and formation of a channel under the gate insulation layer becomes faster, thereby increasing the operating speed of the transistor. By using a thin gate insulation layer, the third transistor may provide an NMOSFET with a faster operating speed than the fourth transistor.

The first insulation layer 510 may be disposed over one surface 110 of the fourth transistor region T4. The second insulation layer 1110 may be disposed over the first insulation layer 510. The first insulation layer 510 and the second insulation layer 1110 may be included in the gate insulation layer of the fourth transistor. The gate insulation layer of the fourth transistor may be thicker than the gate insulation layer of the third transistor. The fourth transistor may be an NMOSFET that uses electrons as carriers, and the fourth transistor region T4 may include a P-type doped region. By using a thick gate insulation layer, the possibility of leakage current is reduced, and the fourth transistor may provide an NMOSFET with higher reliability than the third transistor.

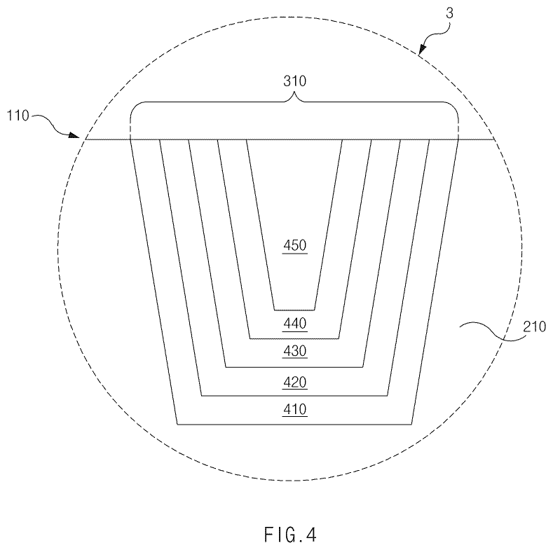

The device isolation structure 310 may be disposed in a trench structure recessed in the first direction D1 from one surface 110 of the semiconductor substrate 10 in the peripheral region 20. The device isolation structure 310 may electrically isolate channels formed under gates located on the first to fourth transistor regions (T1˜T4) from each other. The device isolation structure 310 may include an insulating material and may include a plurality of layers. A more detailed example of the device isolation structure 310 will be described later with reference to FIG. 4.

The first insulation layer 510 may be chemically bonded to a crystalline silicon material that may be located on one surface 110 of each of the second transistor region T2 and the fourth transistor region T4. The first insulation layer 510 may be disposed over the second transistor region T2 and the fourth transistor region T4. The first insulation layer 510 may include, for example, silicon dioxide (SiO₂).

The charge transfer layer 910 may increase the mobility of holes in the PMOSFET. The charge transfer layer 910 may have a lattice constant greater than that of crystalline silicon that may be included in the epitaxial region 210 of the peripheral region 20.

For example, the charge transfer layer 910 may include crystalline (SiGe), which has a larger lattice constant than crystalline silicon and can be more easily formed from crystalline silicon of the epitaxial region 210 of the peripheral region 20 in terms of fabrication process.

The second insulation layer 1110 may be disposed over the charge transfer layer 910 of the first transistor, the first insulation layer 510 of each of the second and fourth transistors, and the third transistor region T3. The second insulation layer 1110 may include, for example, silicon dioxide (SiO₂).

Although not shown in the peripheral region 20 of FIG. 1, source and drain regions included in each transistor may also be disposed in an upper portion of the epitaxial region 210 located adjacent to the gate of each transistor within the epitaxial region 210.

The peripheral region 20 of FIG. 1 may be a cross-sectional view of the semiconductor device (especially a DRAM) taken along a specific cutting line, but the embodiments are not limited only to the DRAM. Any structure in which four transistor gates with different characteristics (e.g., a thin PMOSFET gate, a thick PMOSFET gate, a thin NMOSFET gate, and a thick NMOSFET gate) disposed in the first to fourth transistor regions (T1˜T4) are formed at necessary positions may be included in the semiconductor device according to an embodiment of the present disclosure. For example, in manufacturing a Complementary Metal-Oxide Semiconductor Field-Effect Transistor (CMOSFET) that simultaneously utilizes an NMOSFET and a PMOSFET, when an NMOSFET with a thick gate insulation layer and a PMOSFET with a thin gate insulation layer are used, the transistor disposed in the first transistor region (T1) and a transistor disposed in the fourth transistor region (T4) may be manufactured.

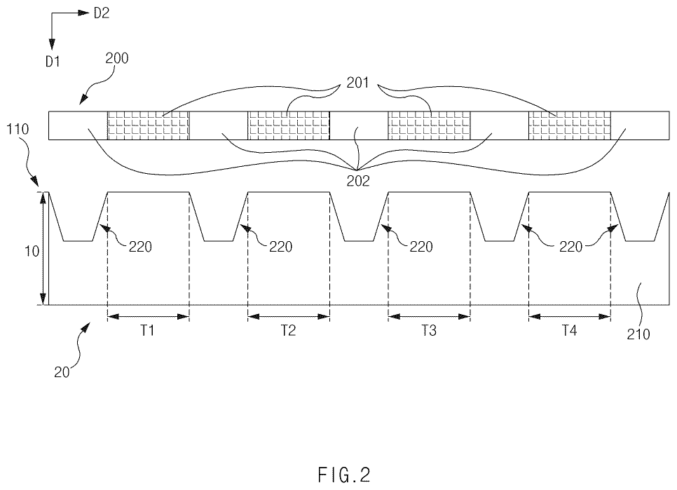

FIGS. 2 to 11 are cross-sectional views illustrating processes of a method for manufacturing the semiconductor device shown in FIG. 1 according to an embodiment of the present disclosure.

More specifically, FIGS. 2 to 11 are views illustrating respective processes for manufacturing gate insulation layers formed over the first to fourth transistor regions (T1˜T4) shown in the peripheral region 20 of FIG. 1.

Hereinafter, a method for manufacturing the cell region 12 will be omitted and a method for manufacturing the peripheral region 20 will be described. Hereinafter, “the semiconductor substrate 10 and the epitaxial region 210” may be understood as “the semiconductor substrate 10 of the peripheral region 20 and the epitaxial region 210 of the peripheral region 20”, respectively.

Referring to FIG. 2, the method of manufacturing a semiconductor device according to an embodiment of the present disclosure may prepare a semiconductor substrate 10 including first to fourth transistor regions (T1˜T4). The semiconductor substrate 10 may include a semiconductor material containing silicon. For example, the semiconductor substrate 10 may include at least one of silicon, monocrystalline silicon, polysilicon, amorphous silicon, silicon germanium, monocrystalline silicon germanium, polycrystalline silicon germanium, silicon carbide (SiC), or combinations thereof. An N-type well may be formed over one surface 110 of each of the first and second transistor regions (T1, T2) using an ion implantation process. A P-type well may be formed over one surface 110 of each of the third and fourth transistor regions (T3, T4) using an ion implantation process.

One or more trench structures 220 recessed by a predetermined depth in the first direction D1 may be formed over one surface 110 of the semiconductor substrate 10. The trench structure 220 may be formed through a photolithography process and an etching process. For example, the etching process may be a dry etching process.

The photolithography process may include a series of processes that include forming a layered structure including photoresist over the semiconductor substrate 10, aligning a first mask 200 having a mask pattern on the semiconductor substrate 10, and performing a development process through an exposure process.

The photoresist material may be a positive photoresist material or a negative photoresist material. The positive photoresist material may be a material formed when a portion exposed to light in the exposure process is removed in the development process, and the negative photoresist material may be a material in which a portion not exposed to light in the exposure process is removed in the development process.

The first mask 200 may include a first light blocking pattern 201 configured to block light during the exposure process, and a first light transmission pattern 202 configured to transmit light. Light incident upon the first mask 200 may be incident in the first direction D1. Among the incident light, light incident upon the first light blocking pattern 201 may not pass through the first mask 200, and light incident upon the first light transmission pattern 202 may pass through the first mask 200.

The first mask 200 is shown as an example in which the photoresist material used in the photolithography process is a positive photoresist material. When the photoresist material is a negative photoresist material, the first light blocking pattern 201 and the first light transmission pattern 202 may be interchanged.

The first mask 200 may overlap the semiconductor substrate 10 in the first direction D1 during the photolithography process. When the first mask 200 is aligned, the first light blocking pattern 201 may overlap the transistor regions (T1˜T4). The first light transmission pattern 202 may be a region excluding the first light blocking pattern 201 in the first mask 200.

After the photolithography process is completed, the photoresist material may be applied on the portion of the semiconductor substrate 10 where the trench structure 220 is not formed, and the photoresist material may not be applied on the portion of the semiconductor substrate 10 where the trench structure 220 will be formed.

The etching process may be performed after the photolithography process is completed.

The dry etching process may be, for example, a process of forming the trench structure 220 on one surface 110 of the semiconductor substrate 10 by ionizing vapor reactants using a plasma system and accelerating ions to apply impact to a target surface to be etched. One or more trench structures 220 may be formed through the etching process. A plurality of trench structures 220 may be formed, and/or may be spaced apart from each other in the second direction D2. The remaining portion of the semiconductor substrate 10 after the trench structure 220 is formed may be used as the epitaxial region 210.

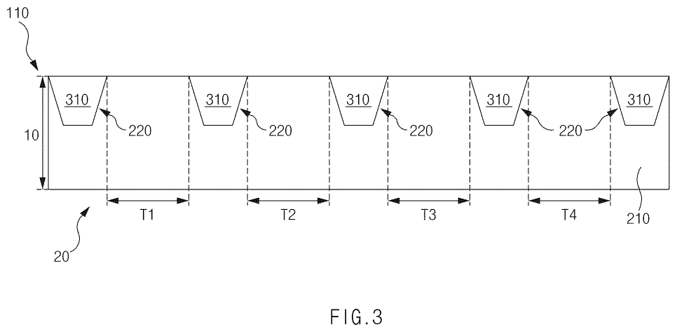

Referring to FIG. 3, a device isolation structure 310 may be formed in the trench structure 220 of FIG. 2. The device isolation structure 310 may be formed using a deposition process.

In FIG. 3, in a situation where the inside of the trench structure 220 is filled with one or more insulation layers through the deposition process and the one or more insulation layers are then formed, a process of removing the portion formed over one surface 110 of the semiconductor substrate 10 is performed, such that the cross-sectional view of FIG. 3 can be obtained. A more detailed structure of the device isolation structure 310 will be described with reference to FIG. 4.

FIG. 4 is a diagram showing an enlarged region 3 of the device isolation structure 310 of FIG. 3.

Referring to FIG. 4, the device isolation structure 310 may include all or part of the first to fifth isolation layers (410, 420, 430, 440, 450).

The first isolation layer 410 may be disposed over an inner wall of the trench structure 220. The first isolation layer 410 may be formed from the epitaxial region 20 containing silicon using an oxidation process. For example, the oxidation process may be a process of exposing the inner wall of the trench structure 220 to oxygen at a high temperature to induce a reaction to produce silicon oxide.

The second isolation layer 420 may be disposed over the first isolation layer 410. The second isolation layer 420 may be, for example, a high quality oxide layer. The second isolation layer 420 may include silicon dioxide and may provide a highly pure isolation layer from which impurities are removed. The second isolation layer 420 may be formed using dry oxygen and a high temperature oxidation process. The second isolation layer 420 may electrically isolate adjacent transistor regions (e.g., the first transistor region T1 and the second transistor region T2) from each other.

The third isolation layer 430 may be formed over the second isolation layer 420. The third isolation layer 430 may be, for example, an ultralow temperature oxide (ULTO) layer. The third isolation layer 430 may be formed at a lower temperature than a process temperature for forming the first or second isolation layers 410 or 420. The third isolation layer 430 may be formed by an atomic layer deposition (ALD) process or a plasma process. For example, the plasma process using plasma may be a process of forming an insulation layer at a low temperature using ionized plasma.

The fourth isolation layer 440 may be formed over the third isolation layer 430. The fourth isolation layer 440 may include, for example, silicon nitride. The fourth isolation layer 440 may expose the third isolation layer 430 to gaseous nitrogen to induce a chemical reaction between silicon contained in the third isolation layer 430 and the gaseous nitrogen.

The fifth isolation layer 450 may be formed over the fourth isolation layer 440. The fifth isolation layer 450 may be, for example, a spin-on dielectric (SOD) material. The fifth isolation layer 450 may be made of a material with excellent gap-fill characteristics. For example, the fifth isolation layer 450 may be formed by spin coating a silicate solution dissolved in an organic solvent and performing a heat treatment (annealing) process.

The device isolation structure 310 according to embodiments of the present disclosure is not limited to a structure including an insulating material having a stacked structure of the first to fifth isolation layers (410, 420, 430, 440, 450), and it should be noted that all types of processes for forming a structure capable of preventing electrical interaction between adjacent transistors can be included in the method for forming the device isolation structure 310.

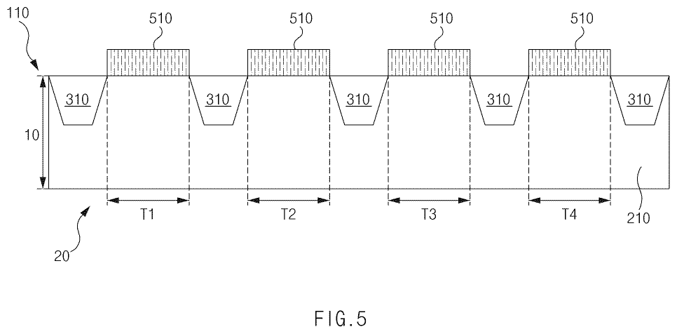

Referring to FIG. 5, a first insulation layer 510 may be formed over one surface 110 of the first to fourth transistor regions (T1˜T4).

The first insulation layer 510 may be formed using at least one of a radical oxidation process, atomic layer deposition (ALD), chemical vapor deposition (CVD), or a wet chemical process. The radical oxidation process may be carried out, for example, at a temperature between 900° C. and 1000° C. When atomic layer deposition (ALD) is performed, a heat treatment process may be performed at a high temperature (e.g., 900° C. or higher) in a subsequent process. When chemical vapor deposition (CVD) is performed, the heat treatment process may be performed in a subsequent process. The wet chemical process may grow a chemical oxide layer using, for example, materials such as H₂O or O₃.

Since the insulation layer (e.g., first insulation layer 510) of the gate of the transistor must be formed of a high-quality layer, the radical oxidation process with a high deposition temperature may be used. When atomic layer deposition (ALD) or chemical vapor deposition (CVD) is performed at a lower temperature than the radical oxidation process, the heat treatment process may be used to increase the density of the insulation layer. Additionally, a high-quality oxide layer may be formed using a wet chemical process.

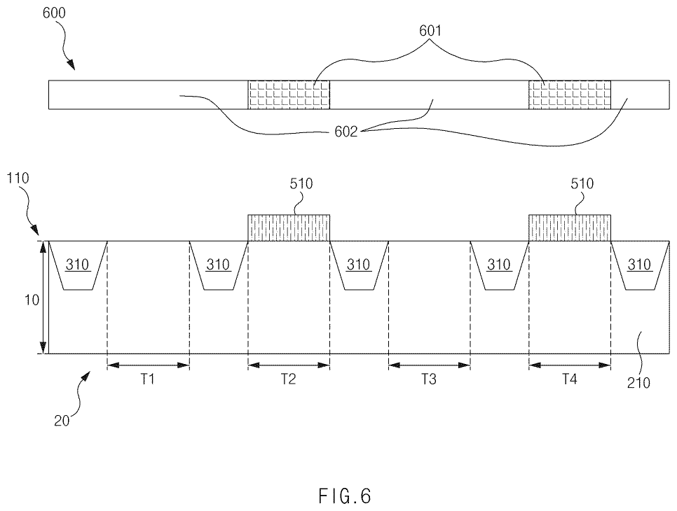

Referring to FIG. 6, the first insulation layer 510 formed over each of one surface 110 of the first transistor region T1 and one surface 110 of the third transistor region T3 in FIG. 5 may be removed. When the first insulation layer 510 is removed, the second mask 600 may be used. The process of removing the first insulation layer 510 from each of the first transistor region T1 and the third transistor region T3 may include performing the photolithography process and performing the etching process.

The photolithography process may include applying a layered structure containing a photoresist material, aligning a second mask 600 with the mask pattern, performing an exposure process, and performing a development process. Since the photoresist material has been described with reference to FIG. 2, a detailed description thereof will herein be omitted for brevity.

The second mask 600 may include a second light blocking pattern 601 and a second light transmission pattern 602. The second light blocking pattern 601 may be a pattern that blocks light during the exposure process. The second light transmission pattern 602 may be a pattern that transmits light during the exposure process.

The second mask 600 is shown as an example in which the photoresist material used in the photolithography process is a positive photoresist material.

The second mask 600 may be aligned on the semiconductor substrate 10 during the photolithography process. When the second mask 600 is aligned, the second light blocking pattern 601 may be aligned with the second and fourth transistor regions (T2, T4). The second light transmission pattern 602 may be a region of the second mask 600 excluding the second light blocking pattern 601.

When the photolithography process is completed, the first insulation layer 510 previously formed over one surface 110 of each of the first transistor region T1 and the third transistor region T3 may be an insulation layer that is no longer coated with the photoresist material by removing the photoresist material.

The first insulation layer 510 formed over the first transistor region T1 and the third transistor region T3 may be removed in the etching process, the first insulation layer 510 disposed over one surface 110 of each of the second transistor region T2 and the fourth transistor region T4 may not be etched by the photoresist material.

The etching process may use precursors containing fluorine (e.g., HF, F, F₂, NF₃, etc.). A chemical reaction may occur when the precursors come into contact with the first insulation layer 510, and the etching process may be completed by removing products generated by the chemical reaction.

When the etching process is completed, the layered structure including the remaining photoresist material may be removed, and FIG. 6 illustrates a state in which the remaining photoresist and the layered structure are removed.

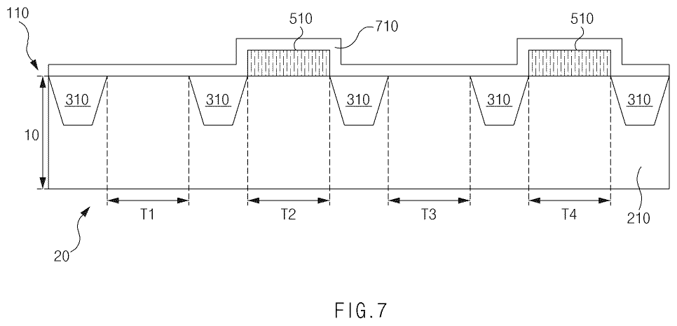

Referring to FIG. 7, the second mask 600 used in FIG. 6 may be removed, and a capping nitride layer 710 may be formed to cover the first insulation layer 510 along one surface 110 of the semiconductor substrate 10 and the surface of the first insulation layer 510.

The capping nitride layer 710 may include at least one of a silicon nitride-based layer (e.g., SiON, SiN, SiCN, SiBCN) or SiCO. The capping nitride layer 710 may serve to protect the second to fourth transistor regions (T2˜T4) in the process of forming the charge transfer layer on one surface 110 of the first transistor region T1 to be performed later.

A method of forming the capping nitride layer 710 may be, for example, a chemical vapor deposition (CVD) process. For example, the capping nitride layer 710 may be formed by applying ammonia-containing gas to either one surface 110 of the semiconductor substrate 10 or the surface of the first insulation layer 510 at high temperature.

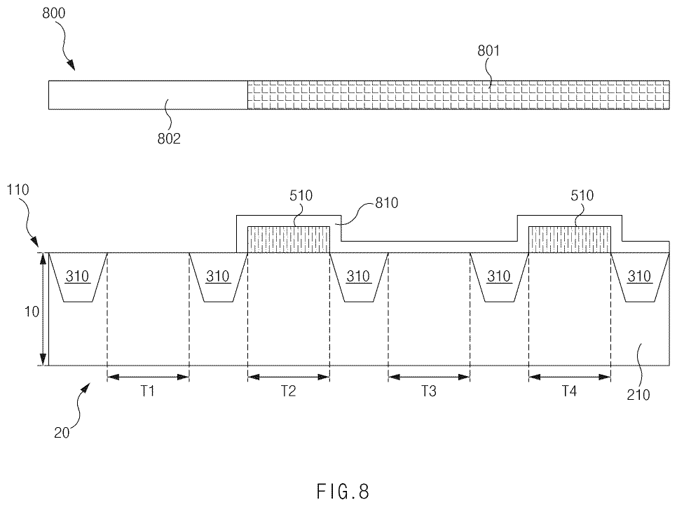

Referring to FIG. 8, the capping nitride layer 710 formed over one surface 110 of the first transistor region T1 in FIG. 7 may be removed. When the capping nitride layer 710 is removed, the third mask 800 may be used. The process of removing the capping nitride layer 710 may include performing the etching process after performing the photolithography process.

The photolithography process may include applying a layered structure containing a photoresist material, aligning a third mask 800 with the mask pattern, performing an exposure process, and performing a development process. Since the photoresist material has been described with reference to FIG. 2, a detailed description thereof will herein be omitted for brevity.

The third mask 800 may include a third light blocking pattern 801 and a third light transmission pattern 802. The third light blocking pattern 801 may be a pattern that blocks incident light during the exposure process. The third light transmission pattern 802 may be a pattern that transmits incident light during the exposure process. The third mask 800 is shown as an example in which the photoresist material used in the photolithography process is a positive photoresist material.

The third mask 800 may be aligned on the semiconductor substrate 10 during the photolithography process. When the third mask 800 is aligned, the third light blocking pattern 801 may be formed to overlap the second to fourth transistor regions (T2˜T4). The third light transmission pattern 802 may be a region of the third mask 800 excluding the third light blocking pattern 801.

When the photolithography process is completed, the capping nitride layer 710 previously formed over one surface 110 of the first transistor region T1 may be uncoated with the photoresist material, and the second to fourth transistor regions (T2˜T4) may be coated with the photoresist material.

The etching process may use precursors containing fluorine (e.g., HF, F, F₂, NF₃, etc.). A chemical reaction may occur when the precursors come into contact with the capping nitride layer 710, and the etching process may be completed by removing products generated by the chemical reaction.

When the etching process is completed, the layered structure including the remaining photoresist material may be removed, and FIG. 8 illustrates a state in which the remaining photoresist and the layered structure are removed.

The remaining capping nitride layer 810 may be a capping nitride layer remaining after the capping nitride layer 710 formed over one surface 110 of the first transistor region T1 is removed.

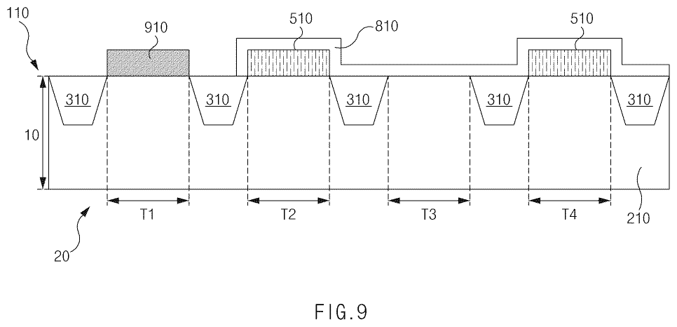

Referring to FIG. 9, a charge transfer layer 910 may be formed over one surface 110 of the first transistor region T1. The charge transfer layer 910 may include silicon germanium (SiGe). The charge transfer layer 910 may have a crystalline structure. The charge transfer layer 910 may be formed through an epitaxial growth process.

The epitaxial growth process to be used for forming the charge transfer layer 910 may be, for example, low pressure chemical vapor deposition (LPCVD), molecular beam epitaxy (MBE), rapid thermal chemical vapor deposition (RTCVD) or vapor phase epitaxy (VPE).

The remaining capping nitride layer 810 may prevent the charge transfer layer 910 from being formed over one surface 110 of the second to fourth transistor regions (T2˜T4) during formation of the charge transfer layer 910.

Crystalline silicon germanium may have a larger lattice constant than crystalline silicon, and the lattice constant may increase as the component ratio of germanium increases. When forming crystalline silicon germanium on crystalline silicon through the epitaxial growth process, the germanium concentration of a reactant to be used during epitaxial growth is proportional to the lattice constant of the crystalline silicon germanium.

If the lattice constant of the charge transfer layer 910 is greater than that of crystalline silicon, compressive stress may occur. A charge transfer layer having compressive stress may increase carrier mobility for holes.

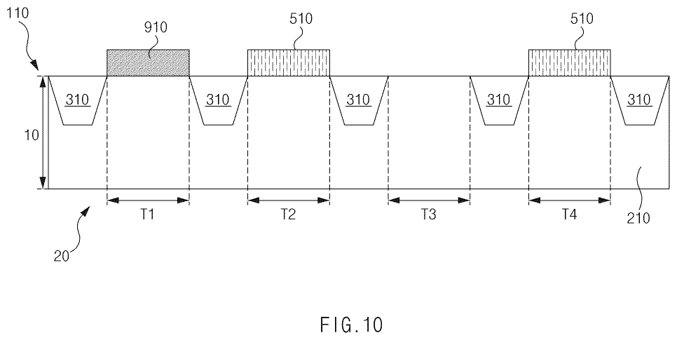

Referring to FIG. 10, after the charge transfer layer 910 is formed, a process of removing the remaining capping nitride layer 810 of FIG. 8 may be performed. The process of removing the remaining capping nitride layer 810 may include a photolithography process and an etching process. In the photolithography process, the first transistor region T1 and the charge transfer layer 910 may be protected with a material such as photoresist, so that the first transistor region T1 and the charge transfer layer 910 are not damaged when the remaining capping nitride layer 810 is removed. In the etching process, the remaining capping nitride layer 810 located on the second to fourth transistor regions (T2˜T4) may be removed using fluorine-containing precursors (e.g., CH₃F). After all remaining capping nitride layers 810 are removed, the protective material of the first transistor region T1 formed in the photolithography process may be removed. FIG. 10 shows a state in which only the charge transfer layer 910 and the first insulation layer 510 remain after the remaining capping nitride layer 810 and the protective material are all removed.

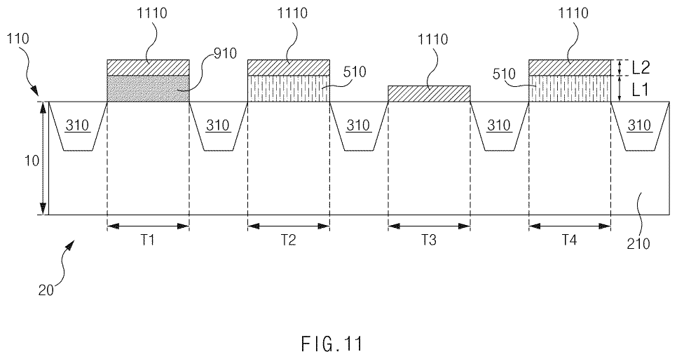

Referring to FIG. 11, a second insulation layer 1110 may be formed over the first to fourth transistor regions (T1˜T4). In the first transistor region T1, the second insulation layer 1110 may be formed over the charge transfer layer 910. In the second transistor region T2, the second insulation layer 1110 may be formed over the first insulation layer 510. In the third transistor region T3, the second insulation layer 1110 may be formed over one surface 110 of the third transistor region T3. In the fourth transistor region T4, the fourth transistor region may be formed over the first insulation layer 510. The second insulation layer 1110 may be formed using one of the processes capable of forming the first insulation layer 510 described with reference to FIG. 5. The second insulation layer 1110 may be formed using the same process as a process that has been used to form the first insulation layer 510.

The first insulation layer 510 may have a first thickness L1, and the second insulation layer 1110 may have a second thickness L2. In an embodiment, the first thickness L1 may be greater than the second thickness L2. The first thickness L1 and the second thickness L2 may vary depending on the progress time of the process for forming the insulation layer and the formation position of the insulation layer. For example, as the progress time of the insulation layer formation process becomes longer, the insulation layer becomes thicker. The longer the insulation layer formation process takes, the thicker the insulation layer may be.

Regarding the formation position of the second insulation layer 1110, according to an embodiment, the thickness L2 of the second insulation layer 1110 may be the same in the first to fourth transistor regions (T1˜T4). In another embodiment, the thickness L2 of the second insulation layer 1110 formed over the first insulation layer 510 may be smaller than the thickness L2 of the second insulation layer 1110 formed over the substrate 10 or the charge transfer layer 910.

In the series of processes described in FIGS. 2 to 11, a person skilled in the art related to the present disclosure may add a cleaning process one or more times if it is determined that removal of unnecessary contaminants is necessary.

In addition, the structure of FIG. 11, which can be derived according to the series of processes described in FIGS. 2 to 11, shows the gate insulation layer of a transistor, and a gate electrode layer configured to receive a voltage as an input may further be formed on the gate insulation layer as needed.

It should be understood that not only gate structures that may be respectively formed in the first to fourth transistor regions (T1˜T4) of the semiconductor device 1, but also the methods for manufacturing the semiconductor device 1 disclosed in FIGS. 2 to 11 are not to be interpreted as being limited to memory devices such as DRAMs or the like, but can also be applied to logic circuits including transistors.

As is apparent from the above description, the embodiments of the present disclosure may provide a method for manufacturing a highly reliable semiconductor device by increasing the reliability of the gate insulation layer.

The embodiments of the present disclosure may provide a variety of effects capable of being directly or indirectly recognized.

Those skilled in the art will appreciate that the embodiments of the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in the present disclosure. Furthermore, the embodiments may be combined to from additional embodiments.

What is claimed is:

1. A method for manufacturing a semiconductor device, the method comprising:
forming a first insulation layer over a second region of a semiconductor substrate including a first region and the second region;
forming a capping layer to cover the first insulation layer located over the second region;
forming a charge transfer layer over the first region; and
forming a second insulation layer over the charge transfer layer located over the first region.

2. The method according to claim 1, further comprising forming a device isolation structure to isolate the first region and the second region from each other.

3. The method according to claim 1, further comprising removing the capping layer after the charge transfer layer is formed and before the second insulation layer is formed.

4. The method according to claim 1, wherein:
the first region includes impurities having a first conductivity type; and
the second region includes impurities having a second conductivity type.

5. The method according to claim 1, wherein the first insulation layer is formed using a radical oxidation process, atomic layer deposition (ALD), chemical vapor deposition (CVD), or a wet chemical process.

6. The method according to claim 1, wherein the semiconductor substrate includes crystalline silicon.

7. The method according to claim 6, wherein the charge transfer layer includes a crystal structure having a lattice constant greater than a lattice constant of the crystalline silicon.

8. The method according to claim 1, wherein the charge transfer layer includes silicon germanium (SiGe).

9. The method according to claim 1, wherein carriers moving inside the charge transfer layer are holes.

10. The method according to claim 1, wherein the capping layer includes silicon nitride-based components.

11. The method according to claim 1, wherein the first insulation layer is thicker than the second insulation layer.

12. A method for manufacturing a semiconductor device, the method comprising:
forming a first insulation layer over second and fourth regions from among first to fourth regions included in a semiconductor substrate;
forming a capping layer to cover the first insulation layer located over the second and fourth regions;
forming a charge transfer layer over the first region;
removing the capping layer after the charge transfer layer is formed; and
forming a second insulation layer over the charge transfer layer located over the first region, the first insulation layer located over the second and fourth regions, and the third region,
wherein:
the first and second regions include impurities having a first conductivity type; and
the third and fourth regions include impurities having a second conductivity type.

13. The method according to claim 12, further comprising forming device isolation structures to isolate the first to fourth regions from each other.

14. The method according to claim 12, wherein the first insulation layer is formed using a radical oxidation process, atomic layer deposition (ALD), chemical vapor deposition (CVD), or wet chemical process.

15. The method according to claim 12, wherein the semiconductor substrate includes crystalline silicon.

16. The method according to claim 15, wherein the charge transfer layer includes a crystal structure having a lattice constant greater than a lattice constant of the crystalline silicon.

17. The method according to claim 12, wherein the charge transfer layer includes silicon germanium (SiGe).

18. The method according to claim 12, wherein carriers moving inside the charge transfer layer are holes.

19. The method according to claim 12, wherein the first insulation layer is thicker than the second insulation layer.

20. The method according to claim 12, wherein the capping layer includes silicon nitride-based components.
